(19) United States
(12) Patent Application Publication
(10) Pub. No.: US 2006/0267162 A1
(43) Pub. Date: Nov. 30, 2006

(54) Lead frame, semiconductor device, method for producing semiconductor device, and injection mold

(75) Inventor: Akimori Kunie, Yamatotakada-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/402,427

(22) Filed: Apr. 11, 2006

(30) Foreign Application Priority Data
Apr. 11, 2005 (JP) 2005-113334

(51) Int. Cl. H01L 23/495

(52) U.S. Cl. 257/666

(57) ABSTRACT

A lead frame 11 is positioned in an injection mold as appropriate, and sealing resin is injected along the flow of resin RF from a runner portion 12. The sealing resin is injected into a cavity (space of the injecting mold that corresponds to a resin sealed portion 15) through a gate portion 13 so that a resin sealed portion 15 is molded by sealing a semiconductor element chip with resin. A deformed portion (hole 16) is formed in the lead frame 11 in accordance with a gate resin portion 13r (gate portion 13 of the injection mold).

### BACKGROUND OF THE INVENTION

This application claims priority under 35 U.S.C. §119(a) on Patent Application No. 2005-113334 filed in Japan on Apr. 11, 2005, the entire contents of which are hereby incorporated by reference.

The present invention relates to a lead frame that can reliably remove sealing resin of a resin gate portion that has been formed in correspondence with a gate portion of an injection mold, to a semiconductor device that uses such a lead frame, and to a method for producing such a semiconductor device, and further to an injection mold that can be applied to production of such a semiconductor device.

Conventionally, semiconductor devices, such as optical sensors and optical pick-ups, that have a resin sealed portion molded through sealing with a transparent resin are known, including devices that have a light receiving element chip as an optical semiconductor element chip mounted on a lead frame or on a metal wiring substrate.

FIG. 12 is a cross-sectional view of a schematic portion that illustrates a method for sealing a conventional semiconductor device with resin. The semiconductor device is shown in perspective with the hatching omitted.

A light receiving element chip 82 is mounted on a lead frame 81 by joining the lead frame 81 to the light receiving element chip 82 using, for example, Ag paste and further connecting a lead terminal 81t, which is a part of the lead frame 81, and the light receiving element chip 82 using, for example, an Au wire as an bonding wire 83. Needless to say, a plurality of the light receiving element chips 82 that are to be separated from one another can be mounted on the lead frame 81.

Subsequently, in order to seal the light receiving element chip 82 with resin using transparent resin, a resin sealed portion 87 is formed by holding the lead frame 81 and the light receiving element chip 82 between injection molds (hereinafter referred to as mold), more specifically between an upper mold 85 and a lower mold 86, and then performing injection molding through injection of transparent resin (molding step).

The mold used for this molding step is provided with a gate portion 88 that communicatively connects the light receiving element chips 82 that are adjacent to each other, in order to form the resin sealed portion 87 in correspondence with each of the plurality of the light receiving element chips 82. Thus, a gate resin portion 89 that is in close contact with the resin sealed portion 87 is formed together with the resin sealed portion 87, in correspondence with the gate portion 88. Mass production can be achieved by resin-molding a plurality of the light receiving element chips 82 simultaneously, however since conversion to single units serving as semiconductor devices is necessary to accomplish a completed product, the gate resin portion 89 is removed.

FIGS. 13(A) and 13(B) are schematic cross-sectional views that illustrate how the gate resin portion that is formed in the molding step of a conventional semiconductor device is removed. FIG. 13(A) shows how the gate resin portion is removed with a gate cut punch, and FIG. 13(B) shows the state after the removal. Such a conventional example is described, for example, in JP2002-184928A.

In the situation shown in FIG. 13(A), a gate cut punch 91 is pressed down in the direction indicated by the arrow so that the gate resin portion 92 is cut and removed from the resin sealed portion 94 of the semiconductor device. However, in a semiconductor device that is sealed with transparent resin, since the elasticity of transparent resin is larger than that of black resin, which is generally used for semiconductor devices such as integrated circuit, the gate resin portion 92 becomes more difficult to break, which may cause an unsuccessful cutting and may result in resin entering the clearance between the gate cut punch 91 and the resin sealed portion 94.

In the situation shown in FIG. 13(B), the gate cut punch 91 returns in the direction indicated by the arrow, and the gate resin portion 92 that remains without being cut returns to its original state due to its elasticity, so that some of the gate resin portion 92 remains as a resin residue. Since the resin residue on the gate resin portion 92 causes a defective shape of the resin sealed portion 94, which can cause problems in subsequent steps, and can affect the reliability, an additional step such as blowing with air (step of blowing off resin) becomes necessary.

In addition, when the gate resin portion 92 is cut, the gate resin portion 92 sometimes does not get cut, causing a resin residue on the resin sealed portion 94 of the semiconductor device, because of sliding of the gate cut punch 91 and dislocation of the cutting position.

Therefore, since the resin residue on the gate resin portion 92 can cause problems in the production process, there is the problem that an additional step of removing the resin residue (step of blowing off resin) becomes necessary, which makes it difficult to improve production efficiency, and can cause a decrease in yield.

### SUMMARY OF THE INVENTION

The present invention has been accomplished in view of the above-described problems, and it is an object thereof to provide a lead frame with which (sealing resin of) a gate resin portion can be removed in a reliable manner by forming a deformed portion that improves the contact between the gate resin portion and the lead frame in the lead frame, and that can prevent occurrence of a resin residue on the gate resin portion.

It is another object of the present invention to provide a semiconductor device with simplified production steps wherein the occurrence of a resin residue on a gate resin portion is prevented by using a lead frame that has the gate resin portion with an improved contact property.

It is yet another object of the present invention to provide a method for producing a semiconductor device with simplified production steps, which prevents occurrence of a resin residue on a gate resin portion by using a lead frame that has a gate resin portion with an improved contact property.

It is yet another object of the present invention to provide a method for producing a semiconductor device with which resin residue on a gate resin portion can be prevented or reduced by providing a constriction on a gate portion of an injection mold so that the gate resin portion can be broken more easily.

It is yet another object of the present invention to provide a method for producing a semiconductor device with which resin residue can be prevented or reduced by preventing slipping of a gate cut punch and reducing a dislocation of a cut location on a gate resin portion through formation of texture on a surface of the gate resin portion by providing texture on a surface of the gate portion of an injection mold.

It is yet another object of the present invention to provide an injection mold with which resin residue on a gate resin portion can be prevented or reduced by providing a constriction on a gate portion of an injection mold so that a gate resin portion can be broken more easily.

It is yet another object of the present invention to provide an injection mold that can prevent or reduce a resin residue through prevention of slipping of a gate cut punch on a gate resin portion and reduction of a dislocation of a cut location on a gate resin portion by providing texture on the surface of a gate portion of the injection mold.

To solve the above-described problems, a lead frame according to the present invention is a lead frame on which a semiconductor chip is mounted and whose resin molded portion is molded by injecting sealing resin through a gate portion of an injection mold, the lead frame comprising a deformed portion that corresponds to a gate resin portion that is formed on the gate portion.

This configuration, in which the contact area of a gate resin portion that is formed so as to correspond to a gate portion relative to a lead frame is enlarged so that the gate resin portion is in an engaged state with the lead frame, makes it possible to improve contact between the gate resin portion (sealing resin) and the lead frame, and to eliminate an incident in which the gate resin portion remains still attached to a semiconductor device since the sealing resin of the gate resin portion is removed in a reliable manner when the gate resin portion is removed.

It is preferable that the lead frame according to the present invention, the deformed portion is a hole.

This configuration, in which the contact area is enlarged with a simple configuration and in which the engaged state is strengthened, makes it possible to improve the contact between the sealing resin and the lead frame.

It is preferable that in the lead frame according to the present invention, the deformed portion is a through-hole.

This configuration makes it possible to improve the contact between the sealing resin and the lead frame in a more reliable manner.

It is preferable that in the lead frame according to the present invention, the deformed portion is one or more grooves.

This configuration, in which the contact area of a lead frame relative to sealing resin at a gate resin portion is further enlarged and in which the area that is in an engaged state is enlarged, makes it possible to further improve the contact between the sealing resin and the lead frame.

It is preferable that in the lead frame according to the present invention, the groove is formed in a direction that crosses a direction of injection of the sealing resin.

This configuration, in which an engaged state of sealing resin relative to a lead frame is further strengthened, makes it possible to further improve the contact between the sealing resin and the lead frame.

It is preferable that in the lead frame according to the present invention, the deformed portion is one or more protrusions.

This configuration, in which the contact area of a lead frame relative to sealing resin at a gate resin portion is enlarged, makes it possible improve the contact between the sealing resin and the lead frame.

It is preferable that in the lead frame according to the present invention, the protrusion is formed at a location positionally aligned with a cut end portion that is a border of a range for cutting the gate resin portion.

This configuration, in which a gate resin portion has a smaller thickness of sealing resin on the protrusion so that the gate resin portion is broken more easily at a location of the protrusion, makes it possible to remove the sealing resin of the gate resin portion in a reliable manner at a cut end portion that is positioned so as to correspond to the protrusion. Thus, variations in the outer dimensions of a semiconductor device can be reduced.

It is preferable that in the lead frame according to the present invention, the protrusion is formed between the cut end portion and the resin sealed portion.

This configuration makes it possible to remove sealing resin of a gate resin portion between a cut end portion and a resin sealed portion in a reliable manner.

It is preferable that in the lead frame according to the present invention, the deformed portion is formed on a plane surface that corresponds to a gate portion of the injection mold. This configuration makes it possible to have the deformed portion act in a reliable manner.

A semiconductor device according to the present invention is a semiconductor device comprising a semiconductor element chip that is mounted on a lead frame, and a resin sealed portion that seals the semiconductor element chip with resin sealed by injecting sealing resin through a gate portion of an injection mold, wherein the lead frame is a lead frame according to any one of claims 1 to 9.

This configuration, in which occurrence of a resin residue caused by sealing resin of a gate resin portion is prevented, makes it possible to eliminate the necessity of a step of blowing off resin and to achieve a semiconductor device with simplified production steps.

It is preferable that in the semiconductor device according to the present invention, the sealing resin is transparent resin.

This configuration makes it possible to achieve a semiconductor device without a resin residue on a gate resin portion even when a sealing is made with transparent resin that has a strong elasticity.

It is preferable that in the semiconductor device according to the present invention, the semiconductor element chip is an optical semiconductor element chip.

This configuration makes it possible to achieve an optical semiconductor device in which occurrence of a resin residue on a gate resin portion is prevented, and to achieve a highly reliable optical semiconductor device with an improved production yield.

A method for producing a semiconductor device according to the present invention is a method for producing a semiconductor device comprising mounting a semiconductor element chip on a lead frame, sealing the semiconductor element chip with resin by injecting sealing resin through a gate portion of an injection mold, and removing the sealing resin at a gate resin portion that is formed at the gate portion, wherein the lead frame is a lead frame according to any one of claims 1 to 9.

This configuration, in which the contact of a gate resin portion (sealing resin) and the lead frame can be improved and in which the sealing resin is removed in a reliable manner when the gate resin portion is removed, makes it possible to prevent occurrence of a resin residue on a semiconductor device after completing a step of removing the gate resin portion.

It is preferable that in the method for producing a semiconductor device according to the present invention, the gate portion has a constriction in a direction that crosses a direction of injection of the sealing resin.

This configuration, in which the gate resin portion (sealing resin) is broken more easily at a location of a constriction, makes it possible to prevent and reduce occurrence of a resin residue on a gate resin portion in a reliable manner.

It is preferable that in the method for producing a semiconductor device according to the present invention, the gate portion has texture on its surface.

This configuration, in which texture is formed on the surface of a gate resin portion so that slipping of a gate cut punch on a the gate resin portion is prevented when the gate resin portion is removed, makes it possible to remove the gate resin portion at an accurate location in a reliable manner, and to prevent and reduce occurrence of a resin residue.

It is preferable that in the method for producing a semiconductor device according to the present invention, the gate portion is positioned so as to correspond to one of the plane surfaces of the lead frame.

This configuration makes it possible to inject sealing resin that has a necessary sealing pressure and to achieve sealing with resin with a precisely controlled manner.

It is preferable that in the method for producing a semiconductor device according to the present invention, the sealing resin is transparent resin.

This configuration makes it possible to achieve a semiconductor device that has no occurrences of a resin residue on a gate resin portion even when a sealing with resin is made using transparent resin that has a strong elasticity.

It is preferable that in the method for producing a semiconductor device according to the present invention, the semiconductor element chip is an optical semiconductor element chip.

This configuration, in which resin residue on a gate resin portion of an optical semiconductor is prevented, makes it possible to achieve a highly reliable optical semiconductor device that has limited problems in processing steps and that has an improved production yield.

An injection mold according to the present invention is an injection mold wherein a semiconductor element chip that has been mounted on a lead frame is resin-sealed by injecting sealing resin from a gate portion, and wherein the gate portion has a constriction.

This configuration, in which a gate resin portion is broken more easily at a constriction, makes it possible to achieve an injection mold that can prevent and reduce the occurrence of a resin residue at the gate resin portion.

An injection mold according to the present invention is an injection mold wherein a semiconductor element chip that is mounted on a lead frame is resin-sealed by injecting sealing resin from a gate portion, wherein the gate portion has texture on its surface.

This configuration, in which slipping of a gate cut punch on a gate resin portion is prevented and in which dislocation of a cutting location on a gate resin portion is reduced, makes it possible to achieve an injection mold wherein the occurrence of a resin residue is prevented or reduced.

### BRIEF DESCRIPTION OF THE DRAWINGS

FIG. 1 is a plan view of a semiconductor device immediately after formation of a resin sealed portion using a lead frame according to Embodiment 1 of the present invention.

FIG. 2 is a schematic cross-sectional view of FIG. 1 along X-X indicated by the arrows, showing an enlarged view.

FIG. 3 is a plan view of a semiconductor device immediately after formation of a resin sealed portion using a lead frame according to Embodiment 2 of the present invention.

FIG. 4 is a schematic cross-sectional view of FIG. 3 along X-X indicated by the arrows, showing an enlarged view.

FIG. 5 is a plan view of a semiconductor device immediately after formation of a resin sealed portion using a lead frame according to Embodiment 3 of the present invention.

FIG. 6 is a schematic cross-sectional view of FIG. 5 along X-X indicated by the arrows, showing an enlarged view.

FIG. 7 is a schematic cross-sectional view of FIGS. 5 and 6, showing an enlarged view of a modified example.

FIG. 8 is a schematic cross-sectional view of FIGS. 5 and 6, showing an enlarged view of another modified example.

FIG. 9 is a plan view of a semiconductor device immediately after formation of a resin sealed portion according to Embodiment 4 of the present invention.

FIG. 10 is a plan view of a semiconductor device immediately after formation of a resin sealed portion according to Embodiment 5 of the present invention.

FIG. 11 is a schematic cross-sectional view of FIG. 10 along X-X indicated by the arrows, showing an enlarged view.

FIG. 12 is a cross-sectional view of a schematic portion that illustrates a conventional method for sealing a semiconductor device with resin.

FIG. 13(A) and 13(B) are schematic cross-sectional views that explain how a gate resin portion that is formed in a molding step of a conventional semiconductor device is removed. FIG. 13(A) shows how the gate resin portion is removed with a gate cut punch, and FIG. 13(B) shows the state after the removal.

### DESCRIPTION OF THE PREFERRED EMBODIMENTS

Hereinafter, embodiments of the present invention will be described with reference to the accompanying drawings.

### Embodiment 1

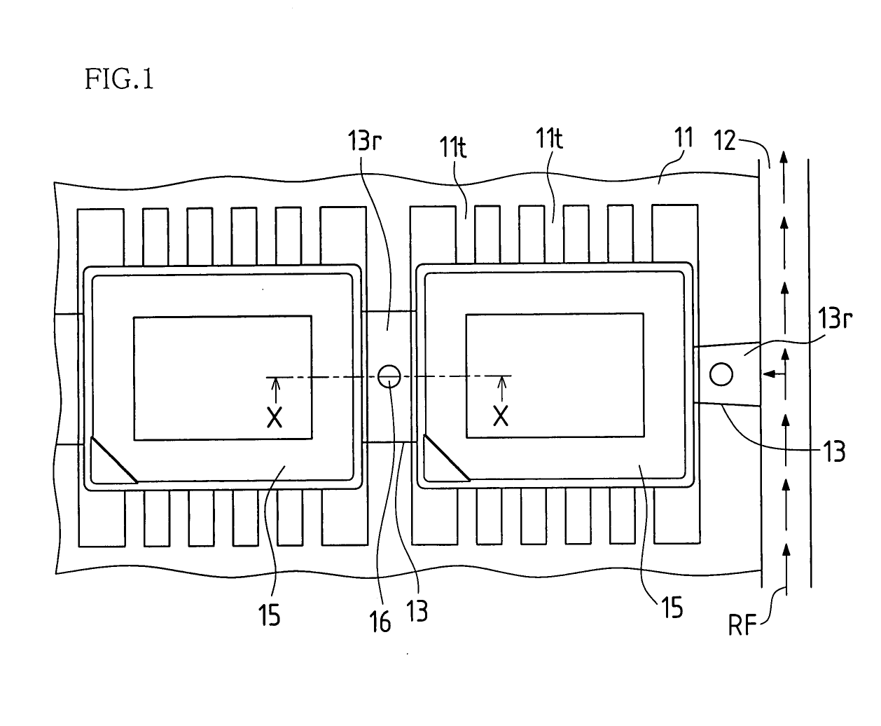

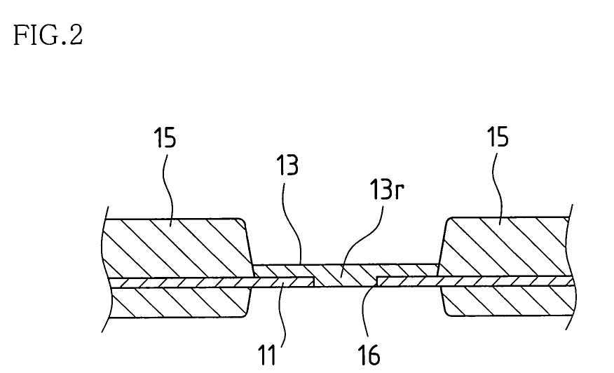

FIG. 1 is a plan view of a semiconductor device immediately after formation of a resin sealed portion using a lead frame according to Embodiment 1 of the present invention. FIG. 2 is a schematic cross-sectional view of FIG. 1 along X-X indicated by the arrows, showing an enlarged view.

A semiconductor device is generally produced through a mounting step, a molding step, and a step of removing a gate resin portion (and a step of separating the lead frame). In the mounting step, a lead frame 11 has a semiconductor chip (not shown) joined thereto using, for example, Ag paste, and further, a lead terminal 11t that constitutes a part of the lead frame 11 is connected to the semiconductor chip using a bonding wire, for example, an Au wire. Thus, the semiconductor element chip is mounted on the lead frame 11.

Subsequently, the lead frame 11 is positioned, as appropriate, in an injection mold (not shown), and sealing resin is injected along a resin flow RE from a runner portion 12. Since a gate portion 13 is positioned so as to contact one of the plane surfaces of the lead frame 11, the sealing resin can be injected with a necessary sealing pressure, and the resin sealing can be precisely controlled.

In a molding step, the sealing resin is injected into a cavity (space of the injection mold that corresponds to a resin sealed portion 15) through the gate portion 13 so that the resin sealed portion 15 is formed by sealing the semiconductor element chip with resin. A state of the lead frame 11 inside of the resin sealed portion 15 is not shown.

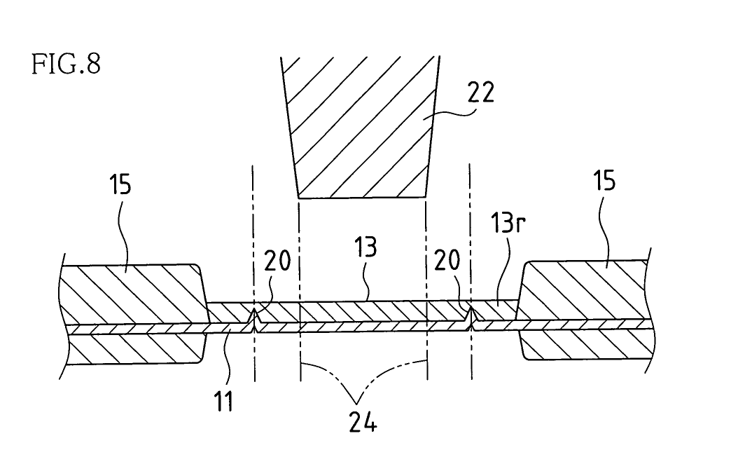

A gate resin portion 13r is formed in correspondence with the gate portion 13 when the resin sealed portion 15 is molded so that the state shown in FIGS. 1 and 2 is achieved. Since the gate resin portion 13r is a part that is not necessary for the individual semiconductor devices, it is removed as appropriate with a gate cut punch 22 in a subsequent step of removing the gate resin portion (see FIGS. 7 and 8).

The lead frame 11 has a deformed portion formed on one of its plane surfaces that corresponds to the gate resin portion 13r (gate portion 13 of the injection mold). In this embodiment, a hole 16 is provided as the deformed portion. With this, a configuration in which the deformed portion can reliably act relative to the gate resin portion 13r is achieved.

The gate resin portion 13r comes to be in a state in which it is completely molded by flowing the sealing resin into the hole 16. Thus, since the contact area of the gate resin portion 13r relative to the lead frame 11 becomes larger, and the gate resin portion 13r achieves a state of engagement with the lead frame 11, it is possible to improve the contact between the gate resin portion 13r (sealing resin) and the lead frame 11.

Since the contact between the gate resin portion 13r and the lead frame 11 is improved, the sealing resin of the gate resin portion 13r is reliably removed together with the lead frame 11 when the gate resin portion 13r and the lead frame 11 at the corresponding location are removed (step of removing the gate resin portion).

Thus, it is prevented that the sealing resin of the gate resin portion 13r becomes attached to the resin sealed portion 15, leading to resin residue. Consequently, a step of blowing off resin, which has conventionally been necessary, becomes unnecessary, and problems in the production process can be prevented, which makes it possible to improve production yield as well as production efficiency, and to achieve a highly reliable semiconductor device that has reduced variations in its outer dimensions.

Since the gate resin portion 13r is reliably removed, a semiconductor device without resin residue can be achieved even when transparent resin that has a stronger elasticity than black resin is used as the sealing resin. Thus, the present invention is suitable for an optical semiconductor device that requires resin sealing using transparent resin.

In addition, since the semiconductor element chip can be an optical semiconductor element chip, a highly reliable optical semiconductor device in which resin residue is prevented can be achieved, and the production yield of optical semiconductor devices can be improved.

Although the hole 16 may be in a depth that does not penetrate through the lead frame 11, by making it a through-hole, the contact area can be further enlarged with a simple configuration, a stronger engaged state can be achieved, and the contact between the gate resin portion 13r and the lead frame 11 can be further improved. More specifically, the hole 16 can be easily formed by etching or punching, as appropriate, the surface of the lead frame 11.

### Embodiment 2

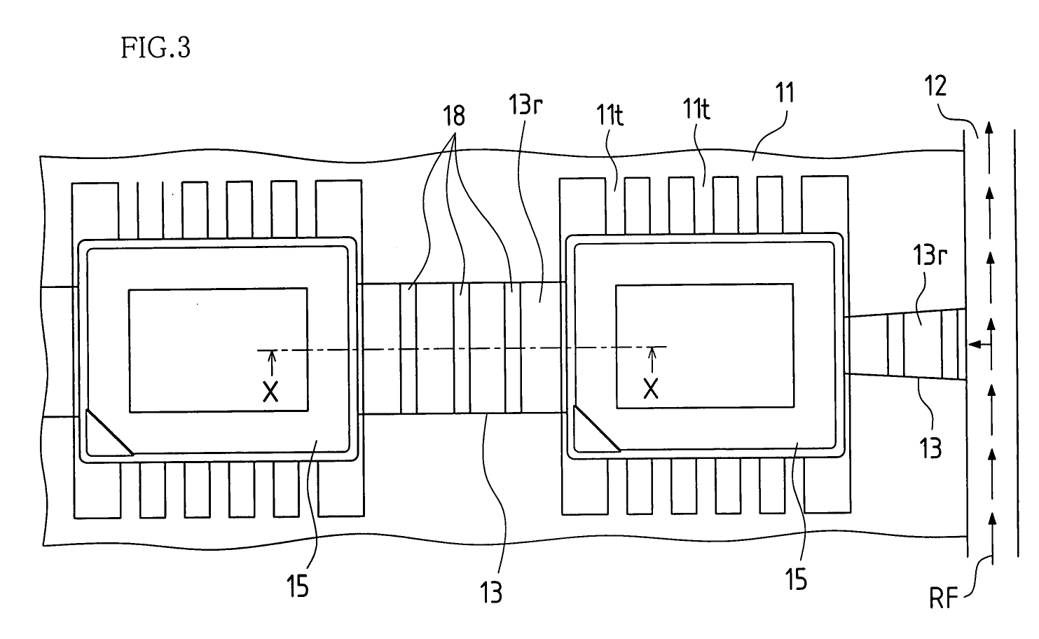

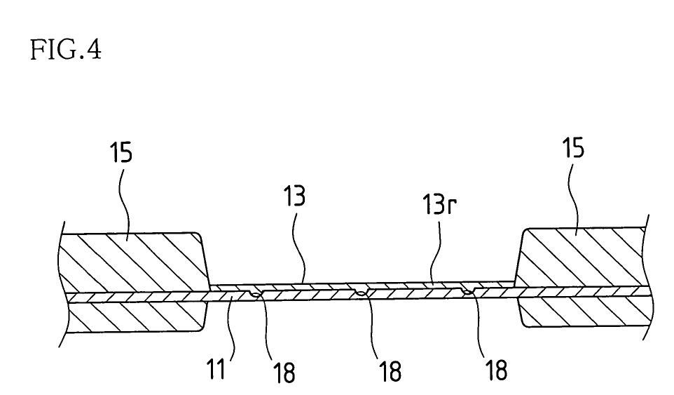

FIG. 3 is a plan view of a semiconductor device immediately after formation of a resin sealed portion using a lead frame according to Embodiment 2 of the present invention. FIG. 4 is a schematic cross-sectional view of FIG. 3 along X-X indicated by the arrows, showing an enlarged view. These FIGS. 3 and 4 show a state in which a gate resin portion 13r is formed in correspondence with a gate portion 13 when the resin sealed portion 15 is molded. In Embodiment 2, the same numeric references are used for the same structural elements as in Embodiment 1 and further detailed explanations thereof are omitted.

A lead frame 11 is provided with grooves 18 as a deformed portion in correspondence with the gate resin portion 13r. Thus, since the gate resin portion 13r comes to be in a state in which molding is achieved by flowing sealing resin into the grooves 18, the contact area of the gate resin portion 13r relative to the lead frame 11 becomes even larger than with the hole 16. And since the gate resin portion 13r is engaged with the lead frame 11, the contact between the gate resin portion 13r (sealing resin) and the lead frame 11 can be further improved.

Since the contact between the gate resin portion 13r (sealing resin) and the lead frame 11 is improved, when the gate resin portion 13r (and the lead frame 11 at the corresponding location) is removed, the sealing resin of the gate resin portion 13r is reliably removed together with the lead frame 11. Thus, it is prevented that the resin sealed portion 15 becomes attached to the gate resin portion 13r, leading to resin residue. Consequently, a step of blowing off resin, which has conventionally been necessary, becomes unnecessary, and problems in the production process can be prevented, which makes it possible to improve production yield and to achieve a highly reliable semiconductor device.

The engaged state can be further improved and the contact can be further improved by forming the grooves 18 in the direction that crosses the injection direction of the sealing resin. The grooves 18 can be easily formed by either etching or punching, as appropriate, the surface of the lead frame 11.

### Embodiment 3

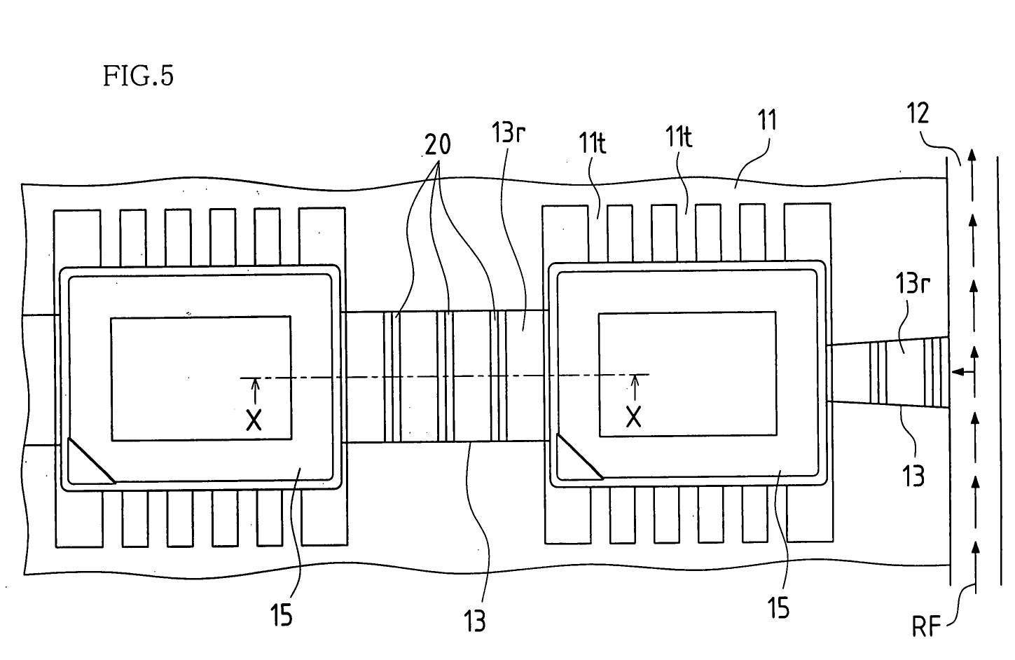

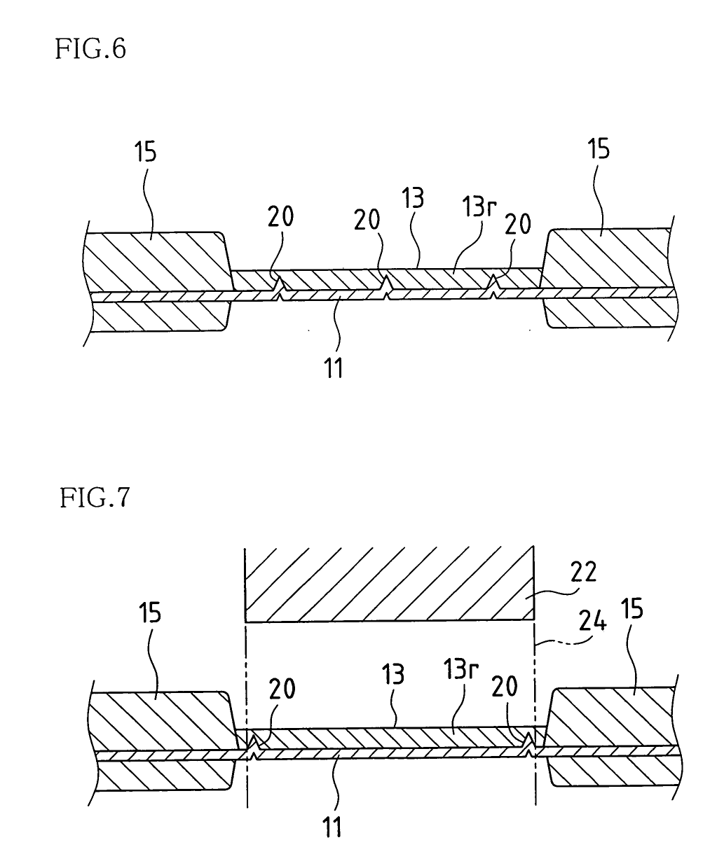

FIG. 5 is a plan view of a semiconductor device immediately after formation of a resin sealed portion using a lead frame according to Embodiment 3 of the present invention. FIG. 6 is a schematic cross-sectional view of FIG. 5 along X-X indicated by the arrows, showing an enlarged view. These FIGS. 5 and 6 show a state in which a gate resin portion 13r is formed in correspondence with a gate portion 13 when a resin sealed portion 15 is molded. In Embodiment 3, the same numeric references are used for the same structural elements as in Embodiment 1 and 2 and further detailed explanations thereof are omitted.

A lead frame 11 is provided with protrusions 20 as a deformed portion in correspondence with the gate resin portion 13r. It is more preferable to have the protrusions 20 in the shape of a ridge in the same directions as the grooves 18 from the perspective that it can enlarge the operative effect. The protrusions 20 can be easily formed by stamping the lead frame 11 from the opposite side as appropriate.

Since the gate resin portion 13r comes to be in a state in which the sealing resin is molded so as to surround the protrusions 20, the contact area of the gate resin portion 13r relative to the lead frame 11 is enlarged, and a state in which the gate resin portion 13r engages the lead frame 11 can be achieved, which makes it possible to improve the contact between the gate resin portion 13r (sealing resin) and the lead frame 11.

Since the contact between the gate resin portion 13r (sealing resin) and the lead frame 11 is improved, the sealing resin of the gate resin portion 13r is reliably removed together with the lead frame 11 when the gate resin portion 13r (and the lead frame 11 at a corresponding location) is removed, which prevents resin residue due to attaching of sealing resin of the gate resin portion 13r to the resin sealed portion 15. Thus, since a step of blowing off resin, which has conventionally been necessary, becomes unnecessary and problems in the production process can be prevented, the production yield can be improved as well as a highly reliable semiconductor device can be achieved.

FIG. 7 is a schematic cross-sectional view showing an enlarged view of a modified example of FIGS. 5 and 6. The gate resin portion 13r is cut and removed with a gate cut punch 22 that is positioned at a cut end portion 24, which is the border of the range where the sealing resin of the gate resin portion 13r is removed (step of removing a gate resin portion).

The thickness of the sealing resin of the gate resin portion 13r is smaller and the sealing resin is easier to break at the location that corresponds to the protrusions 20. For this reason, by forming the protrusions 20 so as to be aligned with the cut end portion 24, the gate resin portion 13r can be broken more easily at locations of the protrusions 20 (cut end portion 24), and the sealing resin of the gate resin portion can be reliably removed.

In other words, since the cut end portion 24 of the gate resin portion 13r is demarcated at locations of the protrusions 20, it is possible to reduce variations in the outer dimensions of the semiconductor device (resin sealed portion 15) after removal of the gate resin portion 13r.

FIG. 8 is a schematic cross-sectional view showing a modified example of FIGS. 5 and 6 in an enlarged view.

The protrusions 20 are formed between the location of the cut end portion 24, which is demarcated by the gate cut punch 22 for cutting and removing the gate resin portion 13r, and the end portion location of the resin sealed portion 15. In other words, the protrusions 20 are formed at locations outside of the cut end portion 24.

By using this configuration, the sealing resin of the gate resin portion 13r that is located between the cut end portion 24 and the resin sealed portion 15 can be removed by the protrusions 20 more easily, which makes it possible to reliably reduce a resin residue that is attached to the resin sealed portion 15.

Needless to say, the shape of the deformed portion and the location of the deformed portion can be adjusted as appropriate in Embodiments 1 to 3.

### Embodiment 4

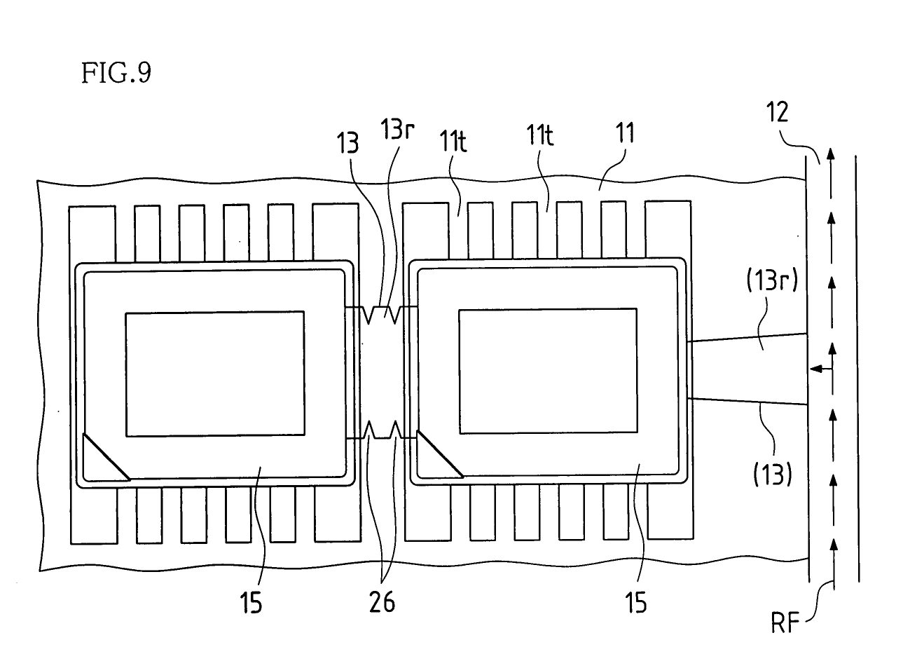

FIG. 9 is a plan view of a semiconductor device immediately after formation of a resin sealed portion according to Embodiment 4 of the present invention. In Embodiment 4, the same numeric references are used for the same structural elements as in Embodiment 1 to 3 and further detailed explanations thereof are omitted.

A lead frame 11 is positioned as appropriate in an injection mold, and sealing resin is injected along the flow of resin RF from a runner portion 12. An injected sealing resin is injected into a cavity through a gate portion 13 so that a semiconductor element chip is sealed with resin and a resin sealed portion 15 is formed (molding step), and the state shown in FIG. 9 is achieved by molding a gate resin portion 13r at the same time.

Since the gate portion 13 of the injection mold is provided with a constricted portions that correspond to constrictions 26, the gate resin portion 13r has the constrictions 26 formed thereon. Since the gate resin portion 13r has the constrictions 26, the sealing resin breaks more easily at the constrictions 26, and the sealing resin of the gate resin portion 13r is reliably removed together with the lead frame 11 when the gate resin portion 13r is removed in a step of removing a gate resin portion. In other words, it is prevented that resin residue occurs due to the sealing resin of the gate resin portion 13r attaching to the resin sealed portion 15.

Although the lead frame 11 may be either a lead frame 11 according to the present invention or a conventional one, it is more desirable that a lead frame 11 according to the present invention is used.

### Embodiment 5

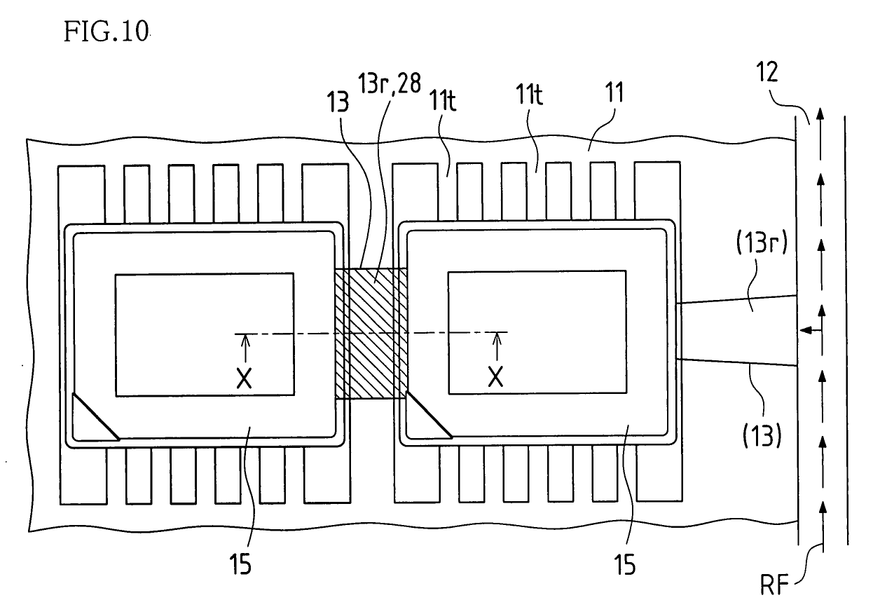

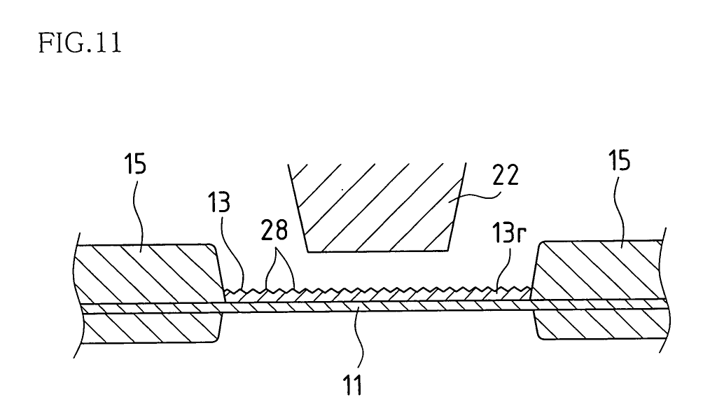

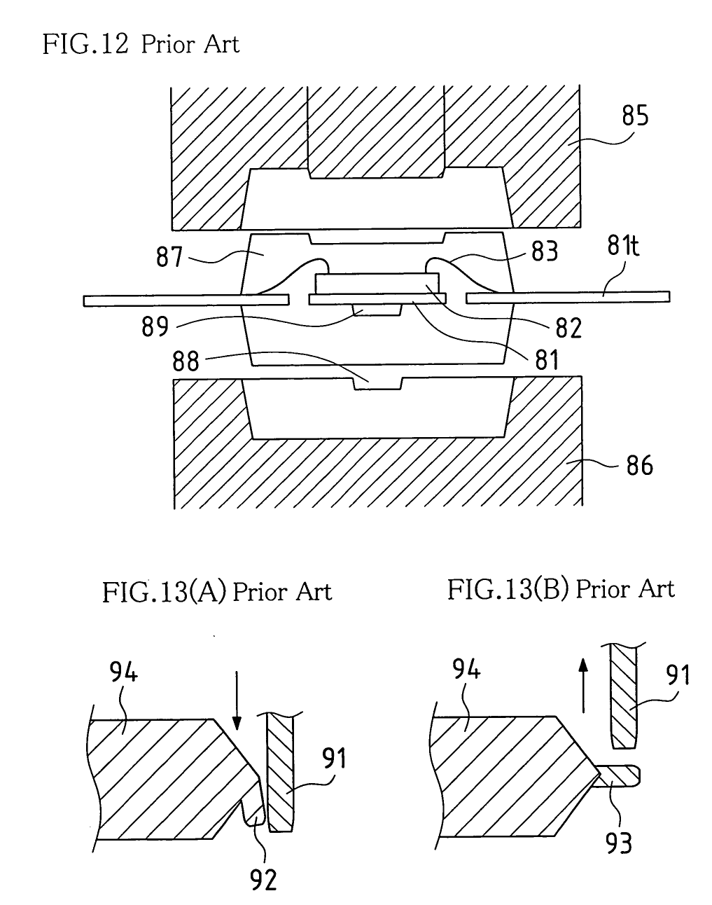

FIG. 10 is a plan view of a semiconductor device immediately after formation of a resin sealed portion according to Embodiment 5 of the present invention. FIG. 11 is a schematic cross-sectional view of FIG. 10 along X-X indicated by the arrows, showing an enlarged view. In Embodiment 5, the same numeric references are used for the same structural elements as in Embodiment 1 to 4 and further detailed explanations thereof are omitted.

A lead frame 11 is positioned in an injection mold as appropriate, and sealing resin is injected along the flow of resin RF from a runner portion 12. The injected sealing resin is injected into a cavity through a gate portion 13 so that a semiconductor element chip is sealed with resin to mold a resin sealed portion 15 (molding step), and the state shown in FIGS. 10 and 11 is achieved by molding a gate resin portion 13r at the same time.

Since the gate portion 13 of the injection mold has a textured portion that corresponds to texture 28 on the surface thereof (surface relative to the surface that faces the gate cut punch 22 at the gate resin portion 13r), the gate resin portion 13r has the texture 28 formed on its surface (surface that faces the gate cut punch 22).

Slipping of the tip surface of the gate cut punch 22 on the surface of the gate resin portion 13r can be prevented and the dislocation of the cutting location of the gate resin portion can be reduced by molding the texture 28 on the surface of the gate resin portion 13r, which makes it possible to prevent and reduce occurrence of a resin residue. In addition, it is possible to reliably reduce variations in the outer dimensions of a semiconductor device.

The lead frame 11 can be the same as in Embodiment 4.

As described in each of the embodiments above, with a lead frame according to the present invention, since a deformed portion that improves the contact between the gate resin portion and a lead frame is provided, the effect of preventing occurrence of a resin residue on the gate resin portion as well as of achieving a semiconductor device without a resin residue can be brought about.

In addition, with a semiconductor device according to the present invention, by using a lead frame that has an improved contact of a gate resin portion, the effect of simplifying the production process by preventing the occurrence of resin residue on the gate resin portion and of achieving a highly reliable semiconductor device that has reduced variations in its outer dimensions can be brought about.

In addition, with a method for producing a semiconductor device according to the present invention, by using a lead frame that has an improved contact of a gate resin portion, the effect of simplifying the production process by preventing the occurrence of resin residue on the gate resin portion and of producing a highly reliable semiconductor device that has reduced variations in its outer dimensions can be brought about.

In addition, with an injection mold according to the present invention, since a constriction is provided on a gate portion, the gate resin portion can be broken more easily and occurrence of resin residue on the gate resin portion can be prevented or reduced. More specifically, since texture are provided on the surface of the gate portion, slipping of a gate cut punch on a gate resin portion can be prevented, and dislocation of the cutting location of the gate resin portion can be reduced, which makes it possible to prevent and reduce resin residue.

The present invention can be embodied and practiced in other different forms without departing from the spirit and essential characteristics thereof. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

What is claimed is:

1. A lead frame on which a semiconductor chip is mounted and whose resin molded portion is molded by injecting sealing resin through a gate portion of an injection mold, the lead frame comprising:
a deformed portion that corresponds to a gate resin portion that is formed on the gate portion.

2. The lead frame according to claim 1, wherein the deformed portion is a hole.

3. The lead frame according to claim 2, wherein the hole is a through-hole.

4. The lead frame according to claim 1, wherein the deformed portion is one or more grooves.

5. The lead frame according to claim 4, wherein the groove is formed in a direction that crosses a direction of injection of the sealing resin.

6. The lead frame according to claim 1, wherein the deformed portion is one or more protrusions.

7. The lead frame according to claim 6, wherein the protrusion is formed at a location positionally aligned with a cut end portion that is a border of a range for cutting the gate resin portion.

8. The lead frame according to claim 6, wherein the protrusion is formed between the cut end portion and the resin sealed portion.

9. The lead frame according to any one of claims I to 8, wherein the deformed portion is formed on a plane surface that corresponds to a gate portion of the injection mold.

10. A semiconductor device comprising:
a semiconductor element chip that is mounted on a lead frame, and
a resin sealed portion that seals the semiconductor element chip with resin sealed by injecting sealing resin through a gate portion of an injection mold,
wherein the lead frame is a lead frame according to claim 1.

11. The semiconductor device according to claim 10, wherein the sealing resin is transparent resin.

12. The semiconductor device according to claim 11, wherein the semiconductor element chip is an optical semiconductor element chip.

13. A method for producing a semiconductor device comprising:
mounting a semiconductor element chip on a lead frame,
sealing the semiconductor element chip with resin by injecting sealing resin through a gate portion of an injection mold, and
removing the sealing resin at a gate resin portion that is formed at the gate portion,
wherein the lead frame is a lead frame according to claim 1.

14. The method for producing a semiconductor device according to claim 13, wherein the gate portion has a constriction in a direction that crosses a direction of injection of the sealing resin.

15. The method for producing a semiconductor device according to claim 13, wherein the gate portion has texture on its surface.

16. The method for producing a semiconductor device according to claim 13, wherein the gate portion is positioned in accordance with one of the plane surfaces of the lead frame.

17. The method for producing a semiconductor device according to claim 13, wherein the sealing resin is transparent resin.

18. The method for producing a semiconductor device according to claim 15, wherein the sealing resin is transparent resin.

19. The method for producing a semiconductor device according to claim 16, wherein the sealing resin is transparent resin.

20. The method for producing a semiconductor device according to claim 17, wherein the semiconductor element chip is an optical semiconductor element chip.

21. The method for producing a semiconductor device according to claim 18, wherein the semiconductor element chip is an optical semiconductor element chip.

22. An injection mold wherein a semiconductor element chip that is mounted on a lead frame is resin-sealed by injecting a sealing resin from a gate portion, and
wherein the gate portion has a constriction.

23. An injection mold wherein a semiconductor element chip that is mounted on a lead frame is resin-sealed by injecting sealing resin from a gate portion, and
wherein the gate portion has texture on its surface.
